(19) United States
(12) Patent Application Publication
(10) Pub. No.: US 2024/0254657 A1
(43) Pub. Date: Aug. 1, 2024

(54) WATER-COOLED SCREEN FOR IMPROVING PULLING RATE OF SILICON CRYSTAL AND MOULD FOR PREPARING THE SAME

(71) Applicant: TCL ZHONGHUAN RENEWABLE ENERGY TECHNOLOGY CO., LTD, Tianjin (CN)

(72) Inventors: Jianhui ZHOU, Tianjin (CN); Wenxia ZHANG, Tianjin (CN); Shengli WANG, Tianjin (CN); Mingyang GONG, Tianjin (CN)

(73) Assignee: TCL ZHONGHUAN RENEWABLE ENERGY TECHNOLOGY CO., LTD, Tianjin (CN)

(21) Appl. No.: 18/040,077

(22) PCT Filed: Nov. 25, 2022
(86) PCT No.: PCT/CN2022/134324

§ 371 Date: Jan. 31, 2023

(30) Foreign Application Priority Data
Jan. 28, 2022 (CN) 202220237316.2

(51) Int. Cl. C30B 35/00; C30B 15/00; C30B 29/06

(52) U.S. Cl. CPC C30B 35/00; C30B 15/00; C30B 29/06

(57) ABSTRACT

The present disclosure provides a water-cooled screen for improving a pulling rate of a silicon crystal, the water-cooled screen being a hollow cylinder including an inner wall surface and an outer wall surface, where at least a portion of the inner wall surface is a curved surface having a plurality of convex or concave points. The present disclosure further provides a mould for preparing the water-cooled screen.

### CROSS-REFERENCE TO RELATED APPLICATION

This application claims priority of Chinese patent application Ser. No. 20/222,0237316.2, filed on Jan. 28, 2022, the content of which is incorporated herein by reference in its entirety.

### TECHNICAL FIELD

The present disclosure relates to the field of Czochralski single crystal technologies, and more particularly, to a water-cooled screen for improving a pulling rate of a silicon crystal and a mould for preparing the water-cooled screen.

### BACKGROUND

With a rapid development of the solar photovoltaic industry, the quality requirements for single-crystal cells are getting increasingly high. As a result, enterprises need to constantly innovate to improve the quality and yield of single crystals and reduce production cost of pulling the single crystals, thereby maximizing economic benefits to the enterprises. How to increase the yield of the silicon crystals in the enterprises and reduce the production cost can be achieved by the following two measures. The first is to increase the feeding mound of raw materials in single crystal production, and the second is to increase the growth rate of the silicon crystals. Pulling silicon crystal growth furnaces are the main equipment for preparing silicon crystal materials. In particular, during the technical innovation of single crystal furnace equipment in recent years, the single crystal furnace equipment itself is equipped with a water cooling device, so that the yield and the quality of the silicon crystals in a unit time are higher and higher, and the cost is lower and lower. However, the demand for technological improvement will not slow down, and there is still a need for continuous optimization and improvement. Under existing equipment processing conditions, the pulling rate has reached the rate limit of single crystal growth. Further, by modifying Standard Operating Procedure (SOP) to forcibly increase the pulling rate, it will undoubtedly increase the risk of breaking bracts, which is detrimental to the improvement of the productivity. In order to improve the pulling rate, existing equipment needs to be optimized to provide a greater temperature gradient.

Current water cooling device is made of 316L stainless steel, and existing water cooling inner surface of the water cooling device is a smooth straight wall. Although the smooth surface facilitates cleaning of the water-cooled screen when the furnace is shut down and removed, the area of heat transfer between the water-cooled screen and the single crystal is limited, which cannot fully exert the effect of cooling the crystals.

### SUMMARY

The present disclosure provides a water-cooled screen for improving a pulling rate of a silicon crystal, and a mould for preparing the water-cooled screen, which is particularly suitable for cooling the silicon crystal when the single crystal is pulled, and solves the technical problem in the prior art that the difference in the longitudinal temperature gradient of the silicon crystal is small due to the poor heat exchange effect of the single crystal resulting from a small heat dissipation area on an inner wall surface of the water-cooled screen.

To solve the above problems, the technical solutions of the present disclosure are as follows.

A water-cooled screen for improving a pulling rate of a silicon crystal is provided, the water-cooled screen being a hollow cylinder including an inner wall surface and an outer wall surface, wherein at least a portion of the inner wall surface is a curved surface having a plurality of convex or concave points.

Preferably, the inner wall surface of the hollow cylinder includes an upper portion and a lower portion, which respectively have a shape selected from a cylinder, a prism, a cone or a pyramid.

Further, the plurality of convex or concave points are disposed on a partial surface or the entire surface of the inner wall surface of the hollow cylinder.

Preferably, the plurality of convex or concave points form a plurality of curves on the inner wall surface.

Preferably, the plurality of convex or concave points are in the form of undulation, and each of the plurality of convex or concave points has one shape of a spherical shape, a cylindrical shape, a tapered shape, or a polygonal shape.

Further, each of the curves is disposed radially or axially along the inner wall surface.

Preferably, when each of the curves is disposed radially along the inner wall surface, the curve is an annular structure or a spiral-rising structure.

Further, when each of the curves is the annular structure, the curve is arranged at a uniform interval in a height direction of the inner wall surface.

Further, when each of the curves is the annular structure, the curve is arranged at a non-uniform interval in a height direction of the inner wall surface.

Further, the annular structure is a closed annular structure or an unclosed annular structure.

Further, when each of the curves is the spiral-rising structure, the curve is uniformly disposed along a radial circumference of the inner wall surface and is arranged at a uniform interval in a height direction of the inner wall surface.

Further, when each of the curves is a closed spiral-rising structure, the curve is continuously disposed from a lower end face of the inner wall surface to an upper end face of the inner wall surface and includes a plurality of convex or concave points that are uninterrupted and uniformly arranged.

When each of the curves is an unclosed spiral-rising structure, a portion of the curve is spirally raised from the lower end face of the inner wall surface to a particular height, and another portion of the curve is spirally raised from a central position of the inner wall surface to the upper end face of the inner wall surface.

Preferably, when each of the curves is disposed axially along the inner wall surface, the curve is disposed in the height direction of the inner wall surface or deflectably disposed in the height direction of the inner wall surface.

Preferably, when each of the curves is deflectably disposed in the height direction of the inner wall surface, the curve is disposed uniformly or spaced adjacent to each other in the circumferential direction of the inner wall surface side by side, and has a closed structure or a non-closed structure.

Preferably, when each of the curves is disposed in the height direction of the inner wall surface, the curve has a closed structure or an unclosed structure.

The disclosure provides a mould for preparing any of the above water-cooled screen.

Further, the mould includes an inner mould and an outer mould, and a curved wall cooperating with the curved surface is provided on a side of the inner mould close to the water-cooled screen.

Each of the concave points in the curved wall is adapted to a corresponding one of the convex points of the inner wall surface, or each of the convex points in the curved wall is adapted to a corresponding one of the concave points of the inner wall surface.

With the water-cooled screen for improving the pulling rate of the silicon crystal and the mold for preparing the water-cooled screen designed according to the present disclosure, the curved surface composed of the curves formed by the plurality of concave points or convex points is provided in the inner wall of the water-cooled screen of the present disclosure. Compared with the conventional straight wall surface of the water-cooled screen, the heat exchange area between the inner wall surface of the water-cooled screen and the silicon crystal can be increased, so that the heat exchange efficiency can be enhanced. Therefore, it can be taken away more heat radiated from the silicon crystal by water cooling per unit time reduce the temperature of the silicon crystal, and increase the longitudinal temperature gradient at the silicon crystal growth interface, thereby accelerating the rate at which the silicon melt is changed from a liquid state to a solid state. Accordingly, the pulling rate of the silicon crystal is increased, and pulling rate of the silicon crystal can be increased by up to 5 mm/h, thereby achieving the purpose of improving the pulling rate of the silicon crystal. The inner wall surface having the curve structure is adaptable to various sizes and models of water-cooled screens, and has high application universality. At the same time, the structure of the present disclosure is relatively simple, and the purpose of increasing the longitudinal temperature gradient of the silicon crystal can be achieved without too much investment or cooperation of other thermal field members. Therefore, the productivity of the silicon crystal is increased, the yield of the silicon crystal production is improved, the production cost is reduced, and the industry competitiveness is enhanced.

### BRIEF DESCRIPTION OF THE DRAWINGS

FIG. 1 is a schematic structural diagram showing a water-cooled screen where a curved surface is provided on a portion of an inner wall surface;

FIG. 2 is a schematic structural diagram showing a water-cooled screen where a curved surface is provided on an entire inner wall surface;

FIG. 3 is a schematic diagram showing a curve structure formed by concave points;

FIG. 4 is an enlarged view of a part A in FIG. 3;

FIG. 5 is a schematic structural diagram showing an inner wall surface where an annular curve of a radially disposed unitary structure is formed;

FIG. 6 is a schematic structural diagram showing an inner wall surface where an annular curve of another radially disposed unitary structure is formed;

FIG. 7 is a schematic structural diagram showing an inner wall surface where an annular curve of a radially disposed semi-unitary structure is formed;

FIG. 8 is a schematic structural diagram showing an inner wall surface where a spiral curve of a radially disposed unitary structure is formed;

FIG. 9 is a schematic structural diagram showing an inner wall surface where a spiral curve of a radially disposed semi-unitary structure is formed;

FIG. 10 is a schematic structural diagram showing an inner wall surface where a vertical curve of an axially disposed unitary structure is formed;

FIG. 11 is a schematic structural diagram showing an inner wall surface where a vertical curve of an axially disposed semi-unitary structure is formed;

FIG. 12 is a schematic structural diagram showing an inner wall surface where a deflected curve of an axially disposed unitary structure is formed;

FIG. 13 is a schematic structural diagram showing an inner wall surface where a deflected curve of an axially disposed semi-unitary structure is formed;

### REFERENCE SIGN ILLUSTRATION

100, water-cooled screen
10, inner wall surface
20, curved surface
21, curve

### EMBODIMENTS OF THE PRESENT DISCLOSURE

The present disclosure is described in detail below with reference to the accompanying drawings and specific embodiments.

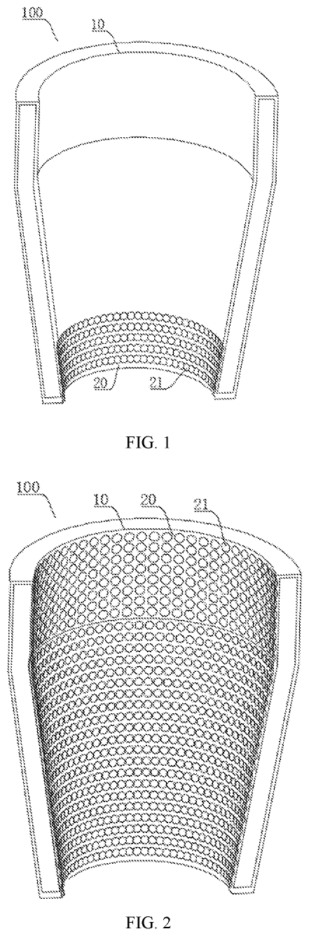

An embodiment of the present disclosure provides a water-cooled screen 100 for improving a pulling rate of a silicon crystal. As shown in FIG. 1, the water-cooled screen is a hollow cylinder including an inner wall surface 10 and an outer wall surface, where at least a portion of the inner wall surface 10 is a curved surface 20 having a plurality of convex or concave points. Specifically, the curved surface 20 may include a plurality of curves 21 formed by a plurality of convex points or concave points and provided on the inner wall surface 10, and be provided at least near a side of the lower end face of the water-cooled screen 100, because the silicon crystal is closer to a solid-liquid interface position, and the surface temperature of the silicon crystal is higher. The temperature gradient in the longitudinal direction of the silicon crystal needs to be adjusted to improve the heat transfer rate in the vicinity of the solid-liquid interface. The curved surface 20 can increase the heat exchange area with the heat radiation of the silicon crystal when pulling the silicon crystal so as to improve the longitudinal temperature gradient of the silicon crystal, thereby accelerating the rate at which the silicon solution is changed from a liquid state to a solid state and further improving the pulling rate of the silicon crystal. Preferably, the upper portion of the inner wall surface 10 of the hollow cylinder may be cylindrical and its lower portion may be in a tapered shape. Preferably, the plurality of convex or concave points may be provided on a underside of the tapered shape of the inner wall surface 10 of the hollow cylinder. Preferably, the plurality of convex or concave points are provided on an entire surface of tapered shape of the inner wall surface 10 of the hollow cylinder, and the tapered shape is a conical shape, as shown in FIG. 2.

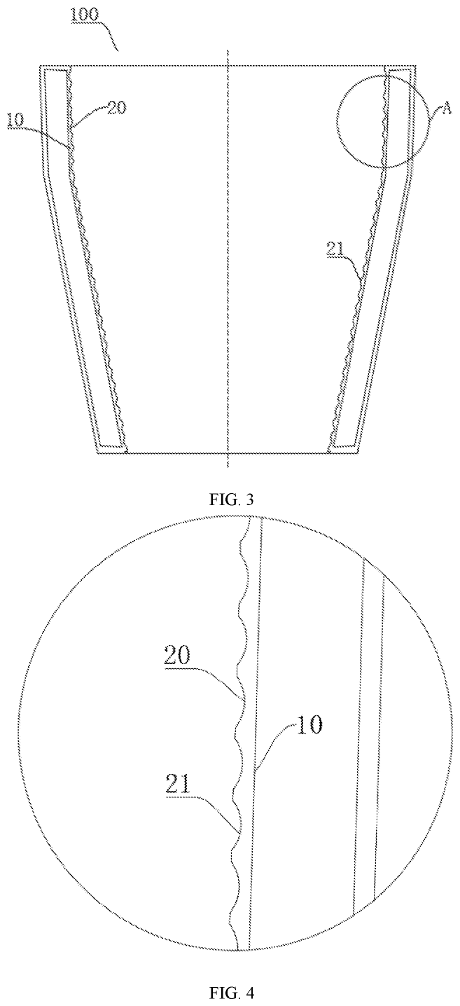

Preferably, the plurality of convex or concave points may form a curve on the inner wall surface. Preferably, the plurality of convex or concave points may be in the form of undulation, as shown in FIGS. 3 and 4, and each of the plurality of convex or concave points may be a stereoscopic structure. Preferably, each of the plurality of convex or concave points may have one shape of a spherical shape, a cylindrical shape, a tapered shape, or a polygonal shape.

Each of the plurality of convex points may be a structure protruded from the inner wall surface 10, and the figures are omitted. Alternatively, each of the plurality of concave points may be a structure embedded in the inner wall surface 10, as shown in FIG. 3. An enlarged view of the concave points is shown in FIG. 4. As long as all the convex points or concave points can form curved points of a uniform structure, an area of the convex points or concave points can be larger than that of the conventional straight wall structure. That is, an area of heat exchange with the outer wall surface of the silicon crystal can be increased. Regardless of the configuration of the convex points or concave points, the curves 21 formed by the convex points or concave points is disposed radially along the inner wall 10 or axially along the inner wall 10. All the convex points or concave points are disposed uniformly along the length of the uniform type of curve 21, and the convex points or concave points on the adjacent curves 21 disposed side-by-side may be longitudinally arranged in the same column or in a staggered arrangement, which is a common arrangement in the art and omitted herein.

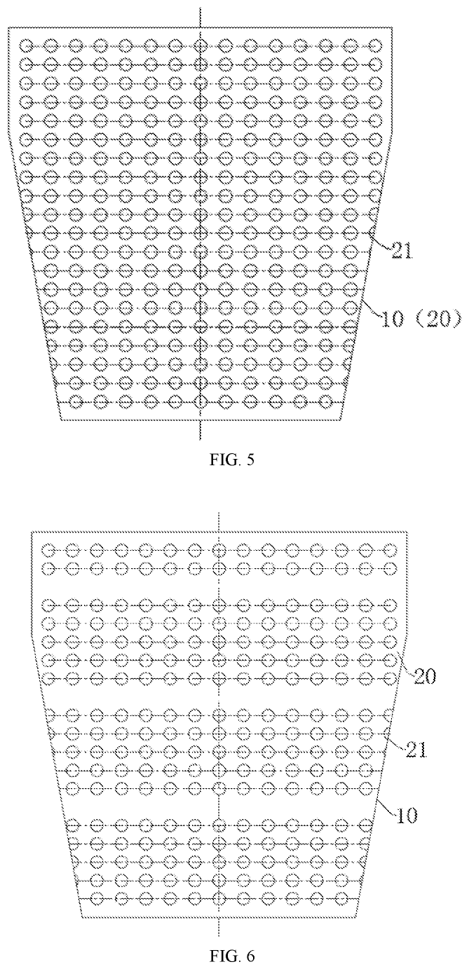

Specifically, FIGS. 5 to 9 show schematic structural diagrams of curves 21 in the inner wall surface 10 when the curves 21 are radially disposed along the inner wall surface 10.

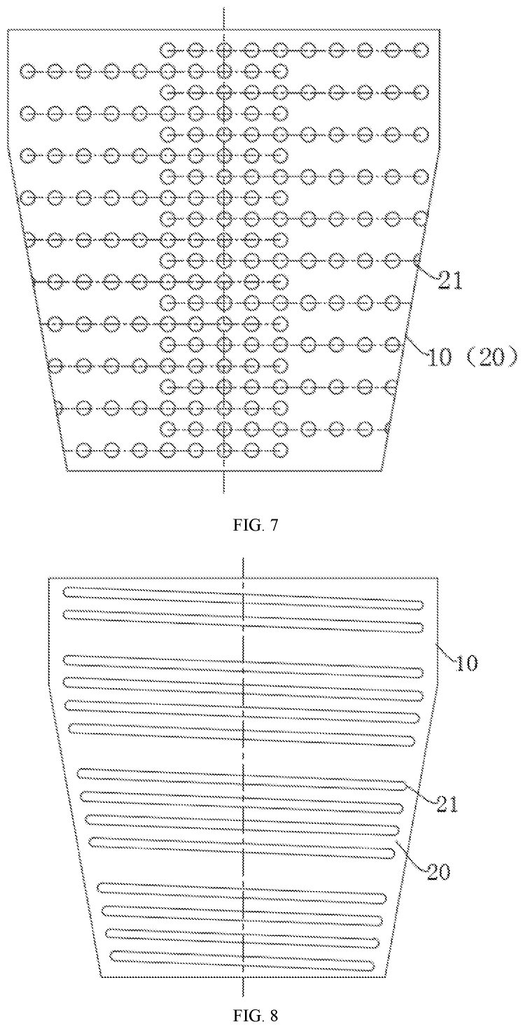

In an embodiment, each of the curves 21 may be an annular structure, and all of the curves 21 having the annular structure are disposed along a radial circumference of the inner wall surface 10. Each of the curves 21 having the annular structures is disposed adjacent to each other in a height direction of the inner wall surface 10, and an expanded view of a portion of the curves 21 on the inner wall surface 10 is shown in FIG. 5. That is, all of the curves 21 having the annular structures are arranged up and down at uniform intervals. Alternatively, all of the curves 21 having the annular structures are arranged at intervals of several heights, and an expanded view of the respective one of the curves 21 on the inner wall 10 is shown in FIG. 6. That is, the curved surface 20 includes a plurality of curves 21 that are closely arranged in different height segments. In FIGS. 5-6, all of the curves 21 are in a unitary structure, i.e., curves 21 in closed annular configuration. The curves 21 having the annular structures may be a semi-unitary structure, i.e., unclosed curves 21 having the annular structures, of which a portion is ½-¾ of a radius of a torus arranged along one end of a bus bar in a forward direction, and of which another portion is ½-¾ of the radius of the torus arranged along another end of the bus bar in a reverse direction. An expanded view of the curves 21 on the inner wall 10 is shown in FIG. 7.

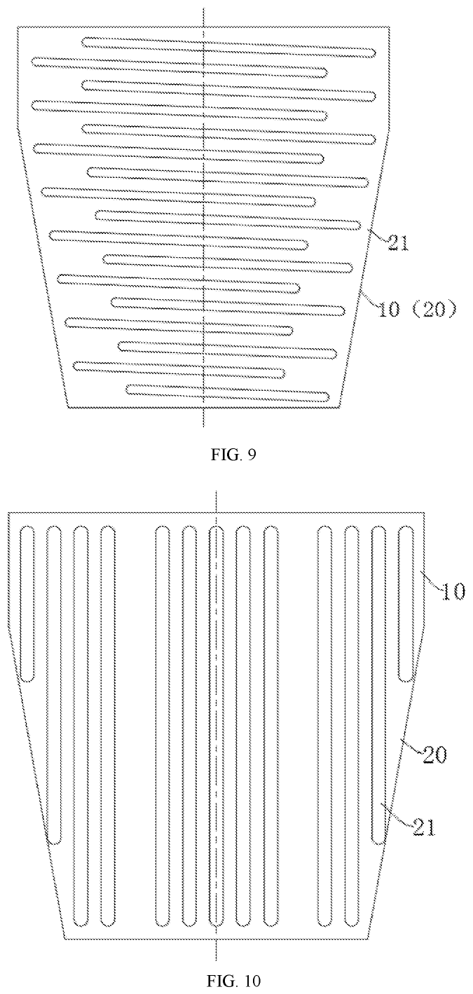

In an embodiment, the curve 21 may also be a spiral-rising structure. As shown in FIGS. 8 to 9, all of the curves 21 having the spiral-rising structures are uniformly disposed along a radial circumference of the inner wall surface 10, and each spiral one of the curves 21 is disposed uniformly and at intervals adjacent to each other along a height direction of the water-cooled screen 100. In yet another embodiment, each of the curves 21 may also be a spiral-declining structure. In the present embodiment and in all subsequent figures, the concave points on the curves 21 are omitted, and only spiral lines formed by tangent lines of the concave points are illustrated, which will not be repeated in detail later.

In this case, spiral curves 21 including the unitary structure, which are disposed continuously from a lower end face of the inner wall surface 10 to an upper end face of the inner wall surface 10, are provided with a plurality of convex points or concave points uninterruptedly and uniformly, and an expanded view of the respective one of the curves 21 on the inner wall surface 10 is shown in FIG. 8. Alternatively, the spiral curves 21 including a semi-unitary structure, of which a portion is spirally raised upward from the lower end face of the inner wall surface 10 to a certain height at a central position, and another portion is spirally raised upward from a central position of the inner wall surface 10 to the upper end face of the inner wall surface 10. An expanded view of the curves 21 on the inner wall surface 10 is shown in FIG. 9. Alternatively, a divided stacked arrangement, which is arranged like a similar arrangement as shown in FIG. 6, includes a plurality of curves 21 that are closely and uniformly disposed in different height segments, and herein, its figure is omitted.

As shown in FIGS. 10-13, when the curved surface 20 includes curves 21 disposed in an axial direction of the inner wall surface 10, the curves 21 are disposed in a height direction of the inner wall surface 10 or deflectably disposed in the height direction of the inner wall surface 10.

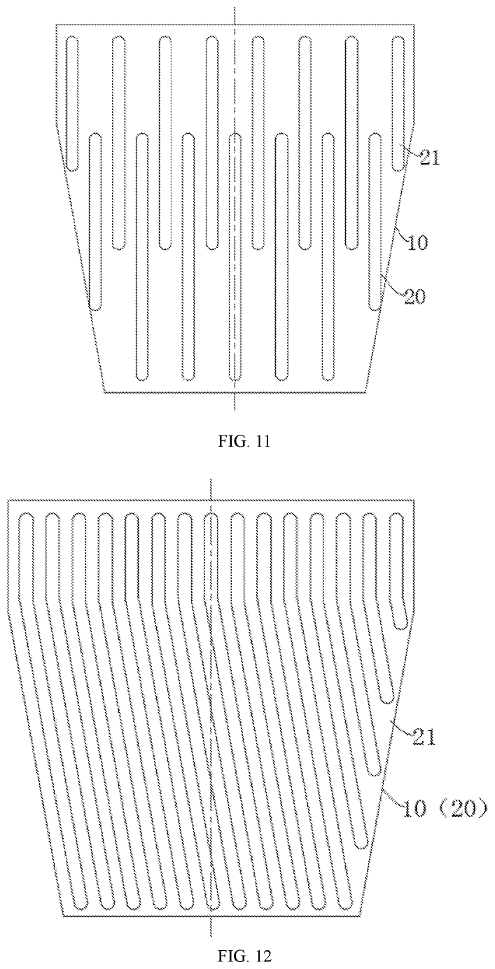

Specifically, the curves 21 are disposed along the height direction of the busbar of the inner wall surface 10, and disposed next to and uniformly along the circumferential direction of the inner wall surface 10, so that the structure thereof is similar to that of FIG. 5, and its figure is omitted. Alternatively, the curves 21 are disposed interruptedly and at intervals along the circumferential direction of the inner wall surface 10 side by side, and an expanded view of the curves 21 on the inner wall surface 10 is shown in FIG. 10. At this time, all the curves 21 are in a unitary structure, that is, disposed uninterruptedly from the lower end face to the upper end face of the inner wall surface 10. Of course, all of the curves 21 may be, when disposed in the height direction of the busbar of the inner wall surface 10, curves 21 of the semi-unitary structure. That is, the height of the curves 21 is the height of a portion of the section where the inner wall surface 10 is located, and is not an entire height of the section where the inner wall surface 10 is located. The curves 21 may be the semi-unitary structure, and an expanded view of the curves 21 on the inner wall surface 10 is shown in FIG. 11. At this time, all the curves 21 of the semi-unitary structure may be disposed to be full along a radial circumferential surface of the inner wall surface 10. Alternatively, all of the curves 21 of the semi-unitary structure are disposed interruptedly and vertically along the radial circumference of the inner wall surface 10 side by side, the structure of which is similar to the distribution in FIG. 10, and its figure is omitted.

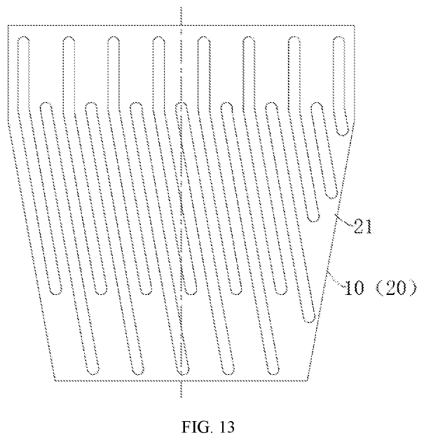

In the embodiment, the curves 21 may be deflectably disposed in the height direction of the busbar of the inner wall surface 10. That is, the amount of lateral deflection of the curve 21 between the upper end face and the lower end face of the inner wall surface 10 in the height direction of the busbar of the inner wall surface 10 should not be too large. Accordingly, an expanded view of the deflected curves 21 of the unitary structure on the inner wall surface 10 is shown in FIG. 12. The largest difference of FIG. 12 from the structure of the spiral curve 21 in FIG. 8 is that the structure in the embodiment is merely twisted in a space of not more than 90° rather than rotated at an angle of 360° with respect to the vertically arranged curves 21. The curves 21 may be evenly distributed on the entire surface of the inner wall surface 10, as shown in FIG. 12, or may be disposed at intervals (its figure is omitted). Of course, the deflection-type curves 21 may be disposed in a semi-unitary structure, of which a portion may be disposed in the lower section of the water-cooled screen 100 and another portion in the upper section of the water-cooled screen 100, and the curves 21 in the upper section and the lower section may be disposed in a staggered manner, and an expanded view of the deflection-type curves 21 in the inner wall surface 10 is shown in FIG. 13.

Regardless of the arrangement of the configuration of the curves 21, when the curves 21 are completely filled with the inner wall surface 10, the water-cooling area is maximized, so that the heat exchange effect on the silicon crystal is maximized. Accordingly, the pulling rate of the silicon crystal is maximized. Compared with the prior art, the curved surface 20 provided on the entire surface of the inner wall surface allows the pulling rate of the silicon crystal to be up to 5 mm/h, so that the pulling time can be saved, thereby improving the production efficiency and reducing the production cost. Furthermore, the curved surface 20 can be popularized to be suitable for manufacturing of any size and any shape of the water-cooled screen 100, and has high universality.

A mould for preparing the water-cooled screen 100 of any of the above is provided, and its figure is omitted.

In particular, the mould includes an inner mould and an outer mould, where a curved wall cooperating with the curved surface 20 is provided on a side of the inner mould close to the inner wall surface 10 of the water-cooled screen 100, and each of the concave points in the curved wall is adapted to a corresponding one of the convex points of the inner wall surface 10, or each of the convex points in the curved wall is adapted to a corresponding one of the concave points of the inner wall surface 10. Since the curved surface 20 is added to the inner wall surface 10, it is necessary to increase the thickness of the stainless steel in the inner wall surface 10 of the water-cooled screen 100 appropriately during the preparation of the water-cooled screen 100. The specific increase may depend on the actual situation, and is not specifically limited herein.

1. The present disclosure designs a water-cooled screen for improving a pulling rate of a silicon crystal and a mould for preparing the water-cooled screen. The curved surface composed of the curve formed by the plurality of concave points or convex points is provided in the inner side wall of the water-cooled screen of the present disclosure. Compared with the conventional straight wall surface of the water-cooled screen, the heat exchange area between the inner wall surface of the water-cooled screen and the silicon crystal can be increased, so that the heat exchange efficiency can be enhanced. Therefore, more heat radiated from the silicon crystal can be taken away by water cooling per unit time, the temperature of the silicon crystal is reduced, and the longitudinal temperature gradient is increased at the silicon crystal growth interface, thereby accelerating the rate at which the silicon melt is changed from a liquid state to a solid state. Accordingly, the pulling rate of the silicon crystal is increased, and the pulling rate of the silicon crystal can be increased by up to 5 mm/h, thereby achieving the purpose of improving the pulling rate of the silicon crystal.

2. The inner wall surface of the curve structure in the present disclosure is adaptable to various sizes and models of water-cooled screens, and has high universality. At the same time, the structure of the present disclosure is relatively simple, and the purpose of increasing the longitudinal temperature gradient of the silicon crystal can be achieved without too much investment or cooperation of other thermal field units. Therefore, the productivity of the silicon crystal is increased, the yield of the silicon crystal production is improved, the production cost is reduced, and the industry competitiveness is enhanced.

The embodiments of the present disclosure have been described in detail above, but the description is only preferred embodiments of the present disclosure and should not be considered as limiting the scope of the present disclosure. All equivalents and modifications made in accordance with the scope of the present disclosure shall fall within the scope of the present disclosure.

What is claimed is:

1. A water-cooled screen for improving a pulling rate of a silicon crystal, the water-cooled screen being a hollow cylinder and including an inner wall surface and an outer wall surface, wherein at least a portion of the inner wall surface is a curved surface having a plurality of convex or concave points.

2. The water-cooled screen of claim 1, wherein the inner wall surface of the hollow cylinder includes an upper portion and a lower portion respectively having a shape selected from a cylinder, a prism, a cone or a pyramid.

3. The water-cooled screen of claim 1, wherein the plurality of convex or concave points are disposed on a partial surface or the entire surface of the inner wall surface of the hollow cylinder.

4. The water-cooled screen of claim 1, wherein the plurality of convex or concave points form a plurality of curves on the inner wall surface.

5. The water-cooled screen of claim 1, wherein the plurality of convex or concave points are in the form of undulation, and each of the plurality of convex or concave points has one shape of a spherical shape, a cylindrical shape, a tapered shape, or a polygonal shape.

6. The water-cooled screen of claim 4, wherein each of the curves is disposed radially or axially along the inner wall surface.

7. The water-cooled screen of claim 6, wherein when each of the curves is disposed radially along the inner wall surface, the curve is an annular structure or a spiral-rising structure.

8. The water-cooled screen of claim 7, wherein when each of the curves is the annular structure, the curve is arranged at an uniform intervals in a height direction of the inner wall surface.

9. The water-cooled screen of claim 7, wherein when each of the curves is the annular structure, the curve is arranged at a non-uniform interval in a height direction of the inner wall surface.

10. The water-cooled screen of claim 8, wherein the annular structure is a closed annular structure or an unclosed annular structure.

11. The water-cooled screen of claim 9, wherein the annular structure is a closed annular structure or an unclosed annular structure.

12. The water-cooled screen of claim 7, wherein when the curve is the spiral-rising structure, the curve is uniformly disposed along a radial circumference of the inner wall surface and is arranged at an uniform interval in a height direction of the inner wall surface.

13. The water-cooled screen of claim 6, wherein, the curve is disposed in the height direction of the inner wall surface or is deflectably disposed in the height direction of the inner wall surface when the curve is disposed axially along the inner wall surface.

14. The water-cooled screen of claim 13, wherein, the curve is disposed uniformly that are adjacent or spaced to each other in the circumferential direction of the inner wall surface side by side, and have a closed structure or a non-closed structure when the curve is deflectably disposed in the height direction of the inner wall surface.

15. The water-cooled screen of claim 13, wherein when the curve is disposed in the height direction of the inner wall surface, the curve is disposed uniformly and adjacent to each other in the circumferential direction of the inner wall surface, and have a closed structure or a non-closed structure.

16. A mould for preparing the water-cooled screen of claim 1.

17. The mould of claim 16, wherein the mould includes an inner mould and an outer mould, and a curved wall cooperating with a curved surface is provided on a side of the inner mould close to the water-cooled screen.

18. The mould of claim 17, wherein each of the concave points on the curved wall is adapted to one of the convex points of the inner wall surface, or each of the convex points in the curved wall is adapted to one of the concave points of the inner wall surface.
